(19) United States
(12) Patent Application Publication
(10) Pub. No.: US 2026/0113037 A1
(43) Pub. Date: Apr. 23, 2026

(54) TOUCH KEYBOARD WITH KEYS

(71) Applicant: SOLID YEAR CO., LTD., NEW TAIPEI CITY (TW)

(72) Inventors: Chao-Hsin LIN, NEW TAIPEI CITY (TW); Yu-Ren LIOU, NEW TAIPEI CITY (TW)

(73) Assignee: SOLID YEAR CO., LTD., NEW TAIPEI CITY (TW)

(21) Appl. No.: 18/980,837

(22) Filed: Dec. 13, 2024

(30) Foreign Application Priority Data
Oct. 18, 2024 (CN) 202411465934.2

(51) Int. Cl. H03K 17/96

(52) U.S. Cl. CPC H03K 17/9622; H03K 2217/96015

(57) ABSTRACT

A touch keyboard includes a support plate, multiple elastomers, multiple keycaps, multiple linkage members, and a capacitive touchpad. The elastomers are disposed on the support plate in a manner protrudes from the top surface of the support plate. The keycaps are mounted on the top ends of the elastomers. The linkage members are positioned between the support plate and the keycaps. The capacitive touchpad is attached to the bottom surface of the support plate for sensing a location and movement trajectory of a conductive object (such as a finger) approaching the keycaps. Thus, the touch keyboard of the present invention places the capacitive touchpad beneath the support plate, which reduces or even eliminates the need for through holes in the capacitive touchpad, thereby minimizing touch dead zones and enhancing touch accuracy.

### BACKGROUND OF THE INVENTION

### 1. Field of the Invention

The present invention relates to a touch keyboard and more particularly, to a touch keyboard that has keys.

### 2. Description of the Related Art

The key-based touch keyboard disclosed in CN 202694270 U installs an aluminum plate on the bottom surface of the capacitive circuit board as support. The pivot seat provided on the top surface of the aluminum plate passes upward through the corresponding through hole of the capacitive circuit board, thus forming an assembly of the linkage member, the capacitive circuit board, and the aluminum plate as a single unit. However, the presence of the through hole in the capacitive circuit board increases touch dead zones, which negatively impacts the touch accuracy of the capacitive circuit board and, in turn, reduces the performance of the key-based touch keyboard.

### SUMMARY OF THE INVENTION

It is one objective of the present invention to provide a touch keyboard, which can increase touch accuracy to enhance performance.

To attain the above objective, the touch keyboard of the present invention comprises a support plate, a plurality of elastomers, a plurality of keycaps, a plurality of linkage members, and a capacitive touchpad. The elastomers are disposed on the support plate in such a way that the elastomers protrude from a top surface of the support plate. The keycaps are mounted on the top ends of the elastomers. When the keycaps are pressed, the elastomers accumulate elastic restoring force. Once the pressure applied to the keycaps is released, the elastic restoring force from the elastomers causes the keycaps to return to their original position. The linkage members are positioned between the support plate and the keycaps for enhancing the tactile feedback and evenly distributing the pressure applied to the keycaps. The capacitive touchpad is attached to a bottom surface of the support plate for sensing a location and movement trajectory of a conductive object approaching the keycaps.

It can be seen from the above that the touch keyboard of the present invention places the capacitive touchpad beneath the support plate, which reduces or even eliminates the need for through holes in the capacitive touchpad, thereby minimizing touch dead zones and enhancing touch accuracy.

Preferably, the bottom end of the elastomer can be directly abutted against the top surface of the support plate or abutted against an elastic film attached on the top surface of the support plate. The elastic film can be integrally formed with the elastomers to enhance structural strength.

Preferably, the support plate further has a plurality of through holes passing through the top and bottom surfaces. Each of the elastomers is received in one of the through holes, and the bottom end of the elastomer is abutted against a top surface of the capacitive touchpad. Such a structural configuration can reduce the overall thickness and shorten the distance between the keycap and the capacitive touchpad to enhance the sensing accuracy of the capacitive touchpad.

Preferably, a conductor element is provided on the top surface of the support plate or the top surface of the capacitive touchpad. The capacitive touchpad has a no-circuit area corresponding to the conductor element. In this way, the no-circuit area can prevent the conductor element from interfering with the signal of the capacitive touchpad, thereby enhancing sensing accuracy.

Preferably, a conductive element is provided on at least one of each keycap, each linkage member, and each elastomer for assisting in signal sensing of the capacitive touchpad.

Preferably, the support plate has a plurality of openings passing through the top and bottom surfaces and corresponding to the conductive elements. By creating the opening, the conductive element is brought closer to the capacitive touchpad when the keycap is pressed, thereby enhancing sensing accuracy of the capacitive touchpad.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a perspective view of a touch keyboard of a first embodiment of the present invention.

FIG. 2 is a partially exploded view of the touch keyboard of the first embodiment of the present invention.

FIG. 3 is a partially sectional view of the touch keyboard of the first embodiment of the present invention.

FIG. 4 is a perspective view of a support plate and a support seat provided by the touch keyboard of the first embodiment of the present invention.

FIG. 5 is a perspective view of the touch keyboard of a second embodiment of the present invention.

FIG. 6 is a partially sectional view of the touch keyboard of the second embodiment of the present invention.

FIG. 7 is a perspective view of elastomers and an elastic film provided by the touch keyboard of the second embodiment of the present invention

FIG. 8 is a partially exploded view of the touch keyboard of a third embodiment of the present invention.

FIG. 9 is a partially sectional view of the touch keyboard of the third embodiment of the present invention.

FIG. 10 is a perspective view of the touch keyboard of a fourth embodiment of the present invention.

FIG. 11 is a partially exploded view of the touch keyboard of the fourth embodiment of the present invention.

FIG. 12 is a perspective view of the touch keyboard of a fifth embodiment of the present invention.

FIG. 13 is a partially exploded view of the touch keyboard of the fifth embodiment of the present invention.

FIG. 14 is a partially sectional view of the touch keyboard of the fifth embodiment of the present invention.

FIG. 15 is a perspective view of the touch keyboard of a sixth embodiment of the present invention.

FIG. 16 is a partially exploded view of the touch keyboard of the sixth embodiment of the present invention.

FIG. 17 is a perspective view of the touch keyboard of a seventh embodiment of the present invention.

FIG. 18 is a partially exploded view of the touch keyboard of the seventh embodiment of the present invention.

FIG. 19 is a partially sectional view of the touch keyboard of the seventh embodiment of the present invention.

### DETAILED DESCRIPTION OF THE INVENTION

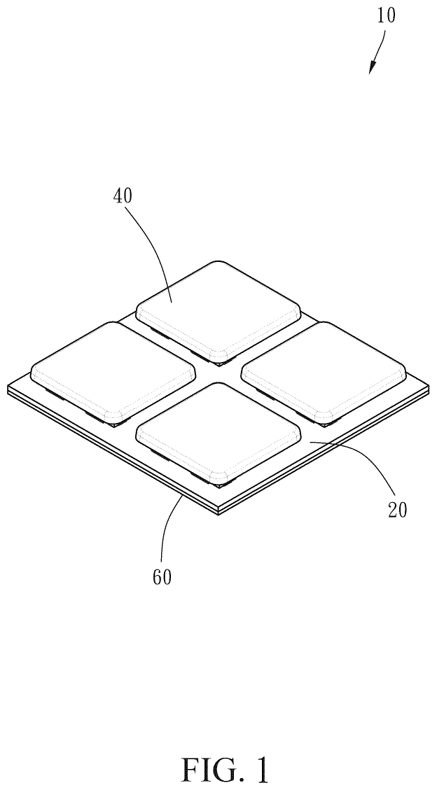

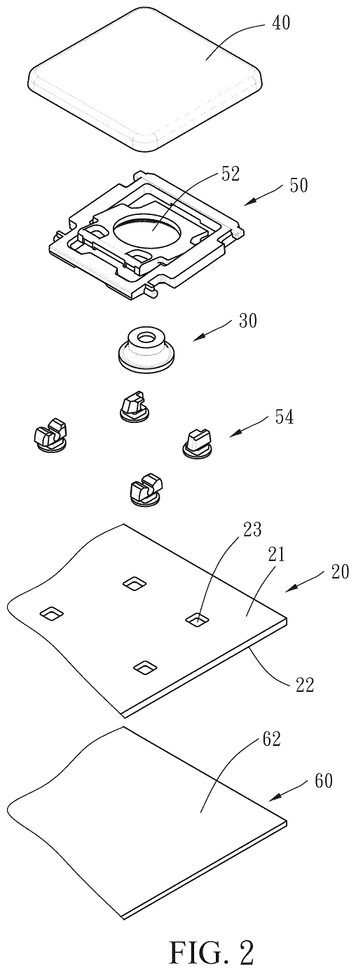

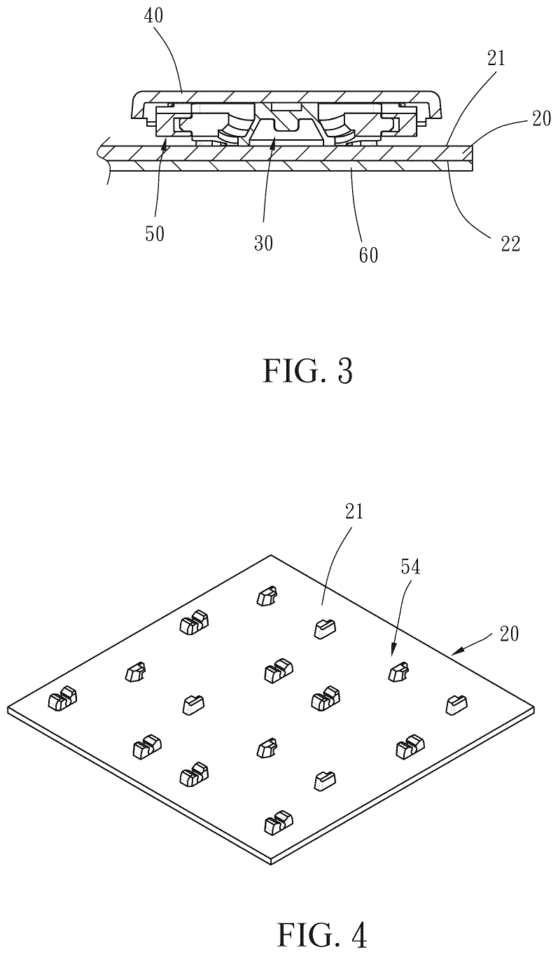

Referring to FIGS. 1 to 3, a touch keyboard 10 of the first embodiment of the present invention comprises a support plate 20, a plurality of elastomers 30, a plurality of keycaps 40, a plurality of linkage members 50, and a capacitive touchpad 60.

The support plate 20 is made of non-conductive material. The support plate 20 has a top surface 21, a bottom surface 22, and a plurality of support holes 23 passing through the top and bottom surfaces 21, 22.

The elastomer 30 is made of non-conductive material, such as rubber. The elastomer 30 is disposed on the support plate 20 in such a way that the elastomer 30 protrudes from the top surface 21 of the support plate 20. In this embodiment, the bottom end of the elastomer 30 is abutted against the top surface 21 of the support plate 20.

The keycap 40 is made of non-conductive material in this embodiment. The keycap 40 is abutted against the top end of the elastomer 30. When the keycap 40 is pressed, the elastomer 30 is compressed to accumulate its elastic restoring force. Once the pressure applied to the keycap 40 is released, the elastic restoring force from the elastomer 30 causes the keycap 40 to return to its original position.

The linkage member 50 is a scissor structure in this embodiment. The linkage member 50 is fitted on the elastomer 30 through a sleeve hole 52 and pivotally mounted on four support seats 54 in a manner that allows vertical movement. Each support seat 54 is inserted through the support hole 23 of the support plate 20 from bottom to top so as to be assembled integrally with the support seat 54. In this way, the linkage member 50 is positioned between the support plate 20 and the keycap 40 for enhancing the operating feel and evenly distributing the pressure applied to the keycap 40.

It should be supplemented here that the support seat 54 is not limited to being independently provided on the support plate 20. The support seat 54 can also be integrally connected to the top surface 21 of the support plate 20 for achieving the effect of enhancing the structural strength, as shown in FIG. 4.

The capacitive touchpad 60 is attached to the bottom surface 22 of the support plate 20 for sensing a location and movement trajectory of a conductive object (such as a finger) approaching the keycaps 40. It should be further clarified that the aforementioned conductive object does not necessarily need to make contact with the keycap 40. As long as it maintains a small distance from the keycap 40 (with this distance depending on the power of the capacitive touchpad 60), the capacitive touchpad 60 can detect the location and movement trajectory of the conductive object.

As described above, when the user's finger slides across the keycaps 40, the capacitive touchpad 60 detects the movement trajectory of the finger. Once the user presses the keycap 40 with their finger, the keycap 40 compresses the elastomer 30 and provides excellent tactile feedback through the linkage member 50 on one hand, and on the other hand, the capacitive touchpad 60 detects a change in capacitance and transmits the signal indicating that the keycap 40 has been pressed. In other words, the touch keyboard 10 of the present invention can serve the dual purpose of both keypress and touch input.

It should be added here that the keycap 40 can be made of conductive material to assist signal sensing of the capacitive touchpad 60; similarly, a part of the linkage member 50 can also be made of conductive material to assist signal sensing of the capacitive touchpad 60.

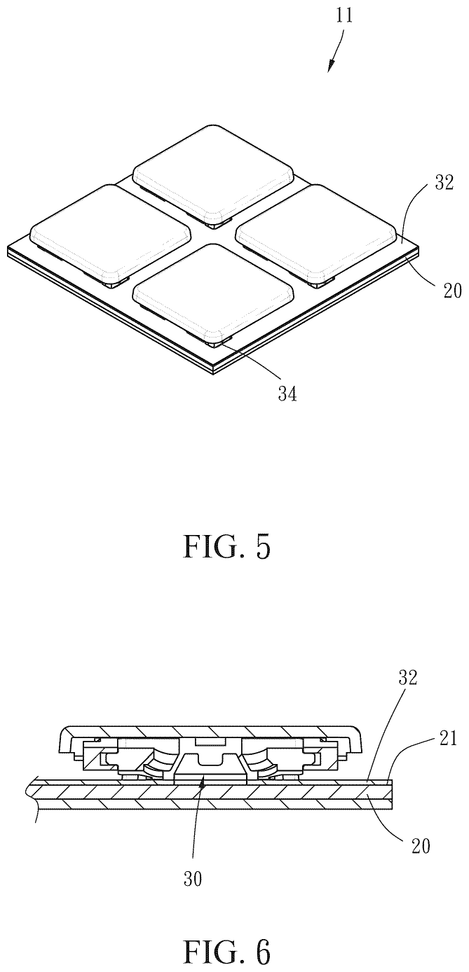

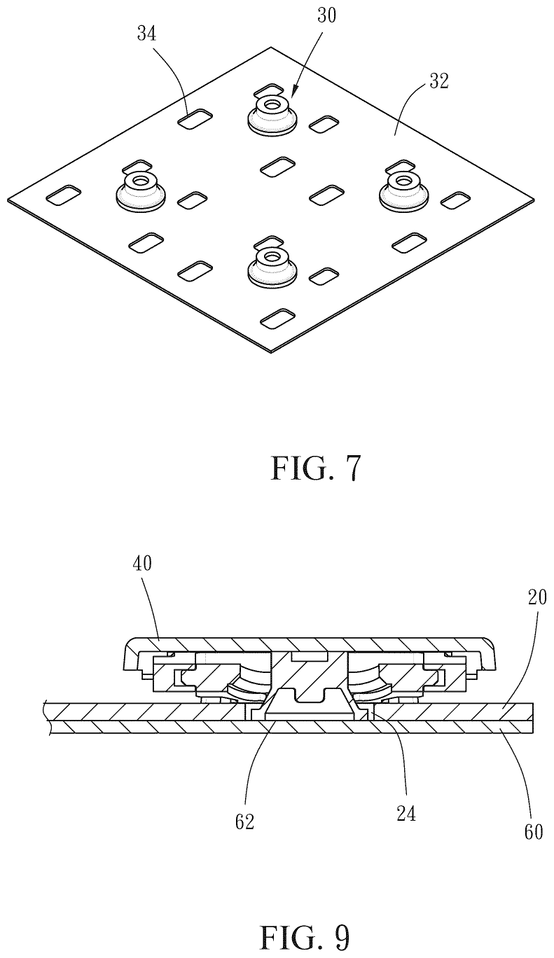

As shown in FIGS. 5 to 7, in the touch keyboard 11 of the second embodiment of the present invention, an elastic film 32 is provided on the top surface 21 of the support plate 20. The elastic film 32 has a plurality of mounting holes 34 for the support seat 54 to be installed. The elastic film 32 and the elastomer 30 can be two-piece structures that are independent of each other. In this case, the top surface of the elastic film 32 are abutted against the bottom ends of all the elastomers 30, allowing the elastomer 30 to move through the elastic film 32 more sensitive. Alternatively, the elastic film 32 and the elastomer 30 may also be integrally connected together (as shown in FIG. 7). This not only enhances the actuation sensitivity but also increases the structural strength.

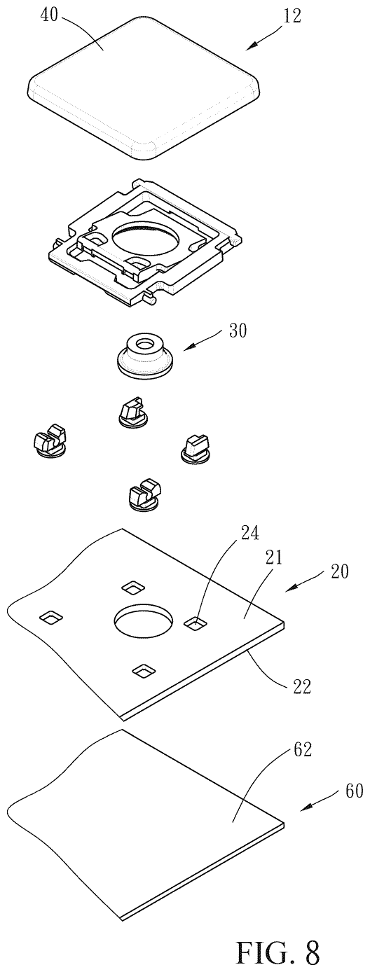

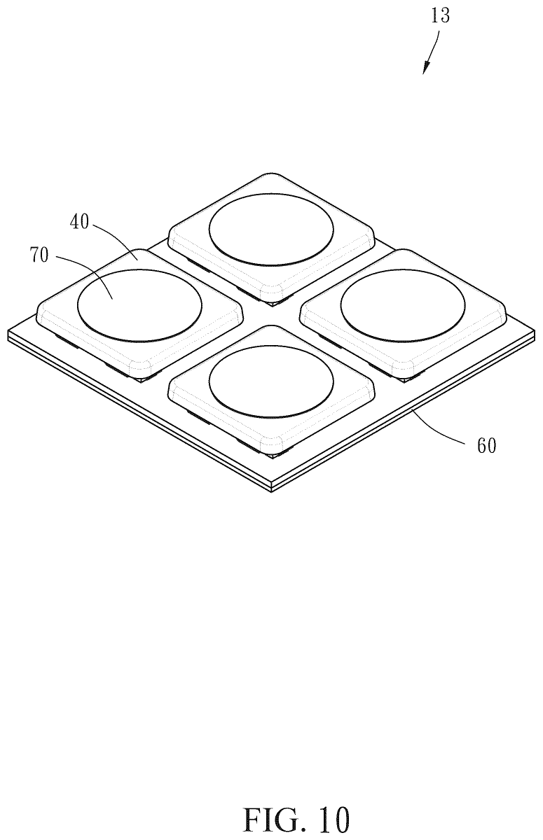

Please refer to FIGS. 8 to 9, the main structure of the touch keyboard 12 of the third embodiment is approximately the same with the first embodiment, but one of the differences therebetween is that the support plate 20 further has a plurality of through holes 24 passing through top and bottom surfaces 21, 22. By using the through hole 24 to accommodate the elastomer 30, the bottom end of the elastomer 30 directly contacts the top surface 62 of the capacitive touchpad 60. Such a structural configuration can reduce the overall thickness and shorten the distance between the keycap 40 and the capacitive touchpad 60 to enhance the sensing accuracy of the capacitive touchpad 60.

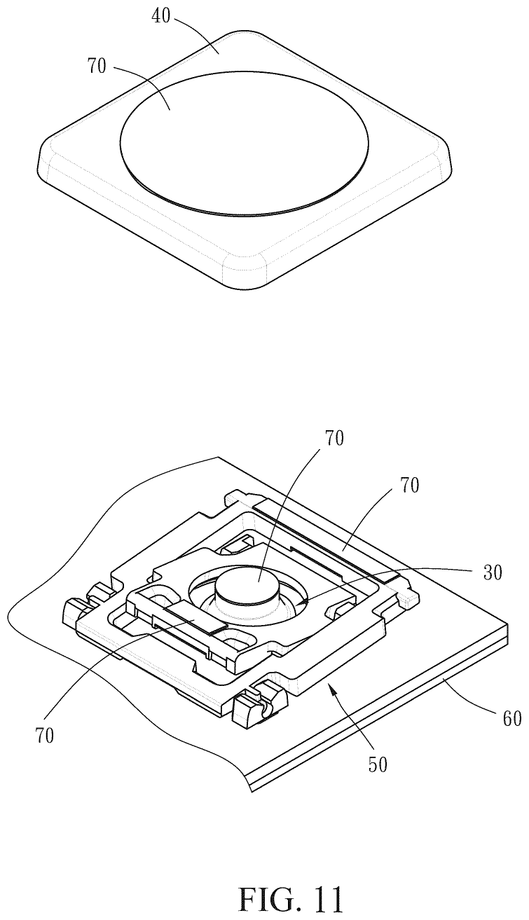

Please refer to FIGS. 10 to 11, the main structure of the touch keyboard 13 of the fourth embodiment is approximately the same with the first embodiment, but one of the differences therebetween is that a conductive element 70 (such as a copper sheet, iron sheet, aluminum sheet, conductive ink, or conductive tape, etc.) can be arranged at any of the following three locations: the top surface of each keycap 40, the top end of each elastomer 30, and the top surface of each linkage member 50. This conductive element 70 is designed to accommodate height variations and assist in amplifying signal detection. The size and shape of the conductive element 70 can be adjusted according to actual needs. The conductive element 70 is used to assist the signal sensing of the capacitive touchpad 60 when the keycap 40 is pressed, thereby enhancing the sensing accuracy of the capacitive touchpad 60.

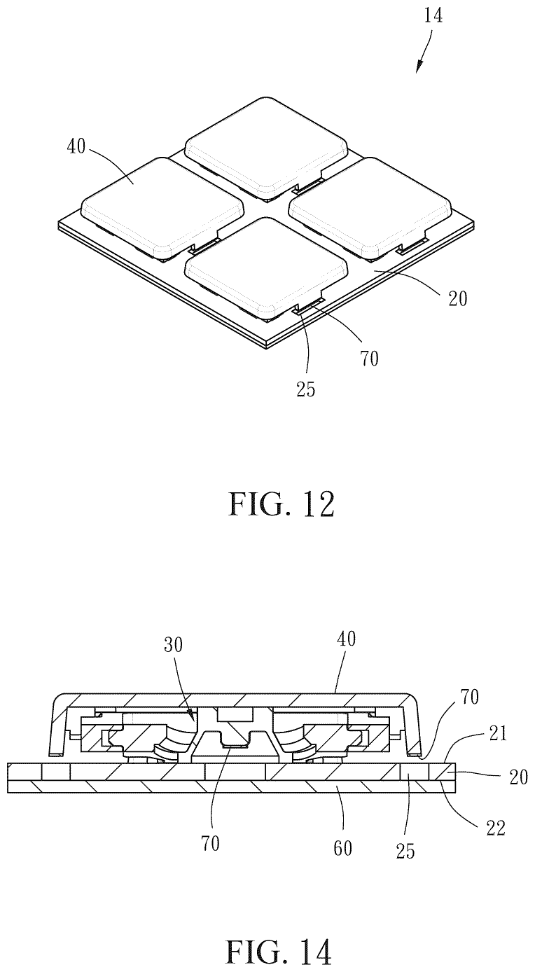

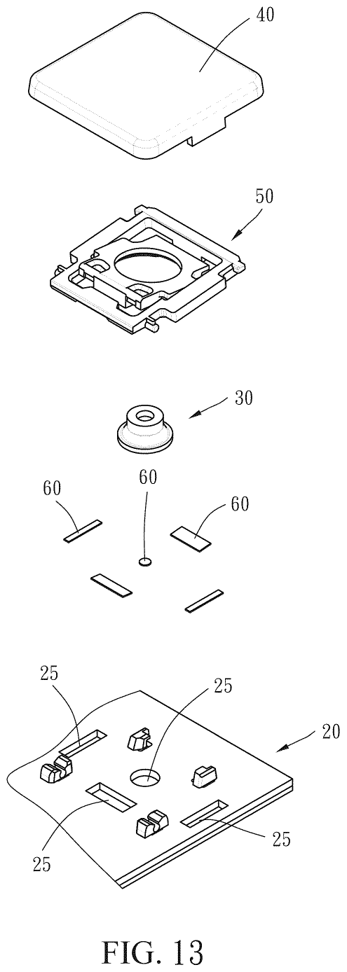

Please refer to FIGS. 12 to 14, the main structure of the touch keyboard 14 of the fifth embodiment is approximately the same with the fourth embodiment, but one of the differences therebetween is that the installation position of the conductive element 70 is different. In this embodiment, the conductive elements 70 are arranged on the bottom surface of the periphery of the keycap 40, the bottom surface of the elastomer 30, and the bottom surface of the linkage member 50. The size and shape of the conductive element 70 can be adjusted according to actual needs. Additionally, the support plate 20 further has a plurality of openings 25 passing through the top and bottom surfaces 21, 22 and corresponding to the conductive elements 70 in a one-to-one manner. By creating the opening 25, the conductive element 70 is brought closer to the capacitive touchpad 60 when the keycap 40 is pressed, thereby enhancing the sensing accuracy of the capacitive touchpad 60.

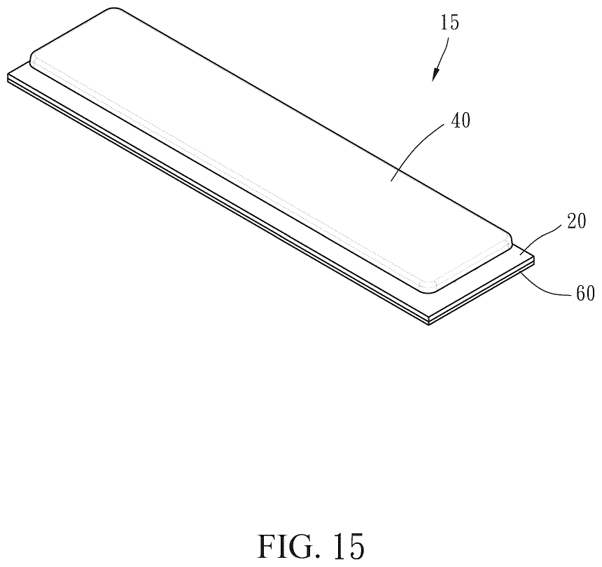

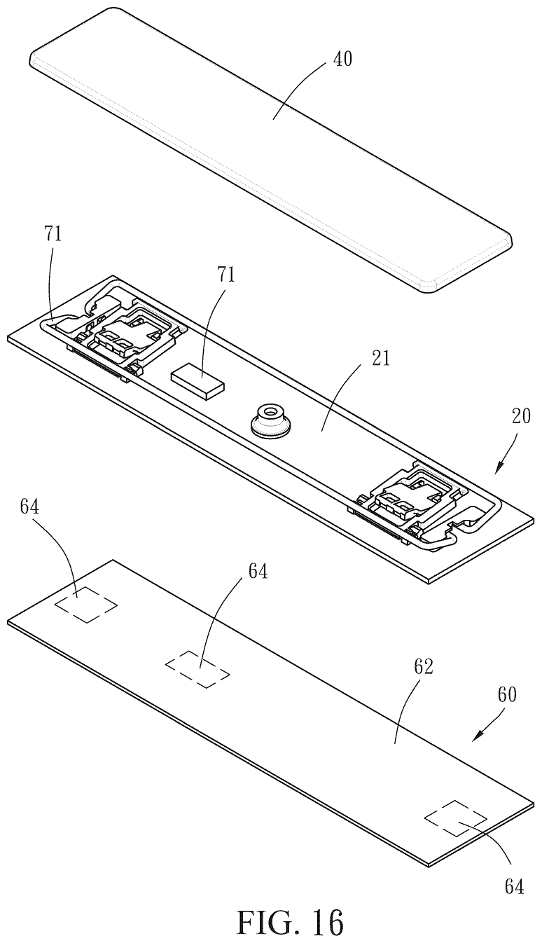

It should be further clarified that the above embodiments primarily apply to typical key scenarios. In special cases, if a conductor element 71 (such as a magnet, balancing rod, or LED, etc.) needs to be arranged on the top surface 21 of the support plate 20 or on the top surface 62 of the capacitive touchpad 60, the circuits in certain areas of the capacitive touchpad 60 may undergo different changes. Please refer to FIGS. 15 to 16, in the touch keyboard 15 of the sixth embodiment of the present invention, the capacitive touchpad 60 is provided with a no-circuit area 64 surrounding the conductor element 71. The no-circuit area 64 can prevent the conductor element 71 from interfering with the signal of the capacitive touchpad 60, thereby enhancing sensing accuracy of the capacitive touchpad 60.

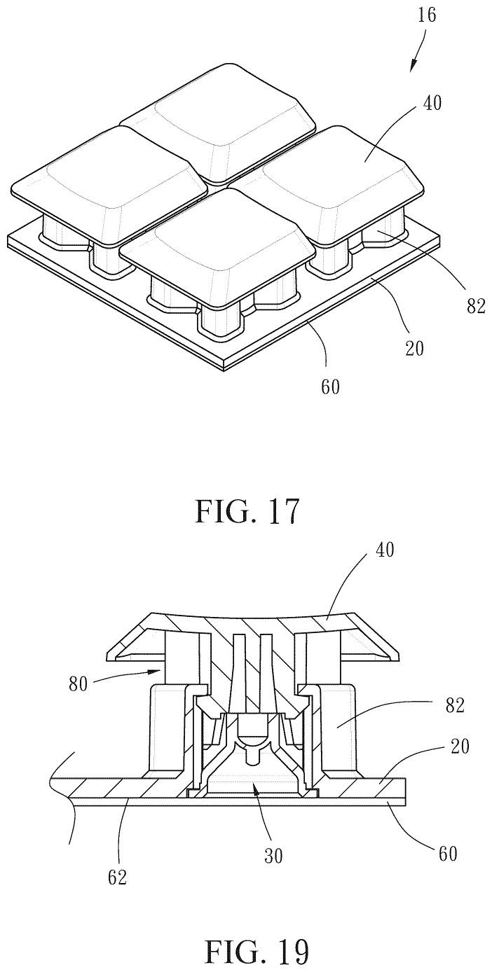

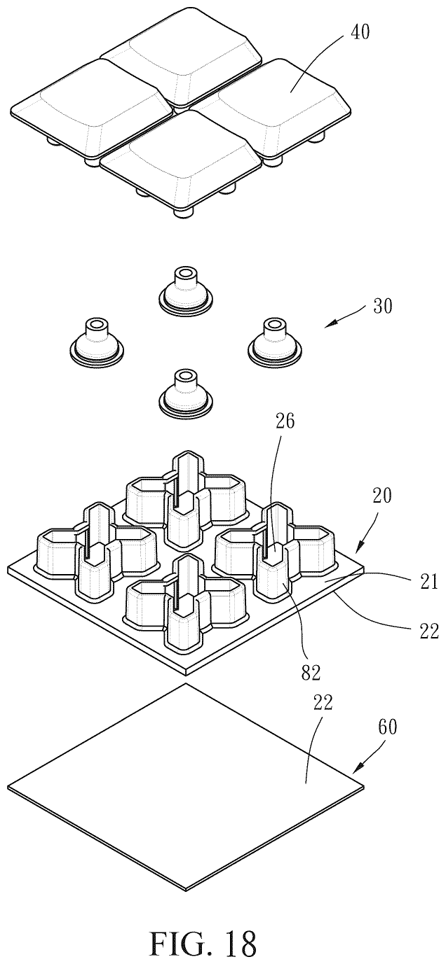

Please refer to FIGS. 17 to 19, in the touch keyboard 15 of the seventh embodiment of the present invention, the support plate 20 and the support seat 82 are integrally connected together, and the keycap 40 and the linkage member 80 are integrally connected together. Furthermore, the support plate 20 has a plurality of perforations 26 passing through the top and bottom surfaces 21, 22. The top surface 21 of the support plate 20 extends upward around each perforation 26 in an integrated manner to form a support seat 82. The elastomer 30 is received in the support seat 82, and the bottom end of the elastomer 30 is abutted against the top surface 62 of the capacitive touchpad 60 through the perforation 26. The linkage member 80 is integrally connected with the bottom surface of the keycap 40 and can be moved up and down through the support seat 82 for enhancing the stability of the keycap 40. Through the above integrated configuration, the effect of simplifying the structure can be achieved.

As indicated above, the touch keyboard 10-16 of the present invention places the capacitive touchpad 60 beneath the bottom surface 22 of the support plate 20, which reduces or even eliminates the need for through holes in the capacitive touchpad 60, thereby minimizing touch dead zones and enhancing touch accuracy and performance.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A touch keyboard comprising:
a support plate having a top surface and a bottom surface;
a plurality of elastomers disposed on the support plate in such a way that the elastomers protrude from the top surface of the support plate;
a plurality of keycaps mounted on top ends of the elastomers;
a plurality of linkage members positioned between the support plate and the keycaps; and
a capacitive touchpad attached to the bottom surface of the support plate for sensing a location and movement trajectory of a conductive object approaching the keycaps.

2. The touch keyboard as claimed in claim 1, wherein a bottom end of each elastomer is abutted against the top surface of the support plate.

3. The touch keyboard as claimed in claim 1, wherein bottom ends of the elastomers are abutted against an elastic film disposed on the top surface of the support plate.

4. The touch keyboard as claimed in claim 3, wherein the elastomers are integrally connected to the elastic film.

5. The touch keyboard as claimed in claim 1, wherein the support plate further has a plurality of through holes passing through the top and bottom surfaces; each of the elastomers is received in one of the through holes, and a bottom end of each elastomer is abutted against a top surface of the capacitive touchpad.

6. The touch keyboard as claimed in claim 1, wherein a conductive element is arranged on the top surface of the support plate for assisting in signal sensing of the capacitive touchpad.

7. The touch keyboard as claimed in claim 1, wherein a conductive element is arranged on at least one of each keycap, each linkage member, and each elastomer for assisting in signal sensing of the capacitive touchpad.

8. The touch keyboard as claimed in claim 7, wherein the support plate has a plurality of openings passing through the top and bottom surfaces and corresponding to the conductive elements.

9. The touch keyboard as claimed in claim 1, wherein a conductor element is arranged on the top surface of the support plate or a top surface of the capacitive touchpad and corresponds to a no-circuit area of the capacitive touchpad.
